(19) United States
(12) Patent Application Publication
(10) Pub. No.: US 2026/0130041 A1
(43) Pub. Date: May 7, 2026

(54) HOLE TRANSPORT BODY, PHOTOELECTRIC CONVERSION ELEMENT, AND COMPOSITION

(71) Applicant: Panasonic Intellectual Property Management Co., Ltd., Osaka (JP)

(72) Inventor: Maki HIRAOKA, Nara (JP)

(73) Assignee: Panasonic Intellectual Property Management Co., Ltd., Osaka (JP)

(21) Appl. No.: 19/440,198

(22) Filed: Jan. 5, 2026

Related U.S. Application Data
(63) Continuation of application No. PCT/JP2024/022697, filed on Jun. 21, 2024.

(30) Foreign Application Priority Data
Jul. 7, 2023 (JP) 2023-112590

(51) Int. Cl. H10K 30/50; H10K 30/86; H10K 85/00; H10K 85/10; H10K 85/50

(52) U.S. Cl. CPC H10K 30/50; H10K 30/86; H10K 85/151; H10K 85/50; H10K 85/761

(57) ABSTRACT

A hole transport body includes: an organic semiconductor; and a nonionic surfactant having a critical micelle concentration of 0.001 g/L or more and 0.080 g/L or less in pure water. A photoelectric conversion element includes a first electrode, a photoelectric conversion layer, a hole transport layer, and a second electrode, and the hole transport layer includes the hole transport body of the present disclosure. A composition for producing a hole transport body includes: an organic semiconductor; a nonionic surfactant having a critical micelle concentration of 0.001 g/L or more and 0.080 g/L or less in pure water; and a solvent.

This application is a continuation of PCT/JP2024/022697 filed on Jun. 21, 2024, which claims foreign priority of Japanese Patent Application No. 2023-112590 filed on Jul. 7, 2023, the entire contents of both of which are incorporated herein by reference.

### BACKGROUND OF THE INVENTION

### 1. Field of the Invention

The present invention relates to a hole transport body, a photoelectric conversion element, and a composition.

### 2. Description of Related Art

Semiconductor devices including silicon which is an inorganic semiconductor material need a high-temperature and high-vacuum process in formation thereof. That makes it difficult to increase the area and reduce the cost for semiconductor devices including silicon.

Meanwhile, organic semiconductor devices including an organic semiconductor material are expected to be used in various applications because, for example, a production process temperature can be decreased and a film can be formed from an organic semiconductor material by a simple process, such as coating, owing to its high solubility in solvents, compared to conventional inorganic semiconductor devices including an inorganic semiconductor material. For example, JP 2019-175970 A discloses a photoelectric conversion element including a buffer layer formed of an organic semiconductor material, the buffer layer being positioned between an active layer and an electrode.

### SUMMARY OF THE INVENTION

The present disclosure aims to provide a hole transport body suitable for increasing the power conversion efficiency of a photoelectric conversion element.

A hole transport body of the present disclosure includes:
an organic semiconductor; and
a nonionic surfactant having a critical micelle concentration of 0.001 g/L or more and 0.080 g/L or less in pure water.

The present disclosure provides a hole transport body suitable for increasing the power conversion efficiency of a photoelectric conversion element.

### BRIEF DESCRIPTION OF THE DRAWINGS

FIG. 1 is a cross-sectional view showing a photoelectric conversion element according to a third embodiment.

FIG. 2 is a cross-sectional view showing a first modification of the photoelectric conversion element according to the third embodiment.

FIG. 3 is a cross-sectional view showing a second modification of the photoelectric conversion element according to the third embodiment.

### DETAILED DESCRIPTION

### Findings on which the Present Disclosure is Based

Organic semiconductor materials included in organic semiconductor devices are required to have high charge mobility. A polymer having a TT-conjugated molecular structure is selected, for example, as a material that transports holes and which can be included in a hole transport layer of a photoelectric conversion element. However, it is difficult to form a uniform film using IT-conjugated molecules because IT-conjugated molecules have highly anisotropic molecular structures and a steric higher-order structure is likely to be formed of anisotropically stacked TT-conjugated molecules. Hence, to drive a device including the above material, it is necessary to suppress formation of a higher-order structure and thereby improve interfacial adhesion between layers and prevent a layer short due to a gap.

A dynamic drying process, such as spin coating, is generally effective in suppressing formation of a higher-order structure of a film and forming a flat film. According to this method, formation of a higher-order structure is suppressed to form a flat film by applying a solution in which a semiconductor material is dissolved and then quickly vaporizing the solvent of the solution under an in-plane stress. However, in the case of an area increasing process where adequate control over vaporization conditions is difficult, it is difficult to sufficiently improve the manufacturing reliability by adjusting processing conditions. An additive that promotes flattening may be added to an organic semiconductor material to facilitate flattening of a film independently of drying conditions. However, the additive can hinder electrical conduction of the semiconductor material, leading to degradation rather than improvement of the device performance.

For example, in the case where an organic semiconductor material is included in a photoelectric conversion element such as a solar cell, it is difficult to increase the power conversion efficiency of the photoelectric conversion element.

Conventionally, a hole transport material includes, for example, a dopant for increasing the hole mobility as well as an organic semiconductor which is a material that transports holes. A solvent is adjusted to disperse these two components. Therefore, an additive that suppresses formation of a higher-order structure of a film has not drawn attention. The present inventors focused on this and studied a relationship between a surfactant and properties of a photoelectric conversion element. As a result, the present inventors have newly found that a hole transport body produced using a nonionic surfactant as an additive improves the power conversion efficiency of a photoelectric conversion element. On the basis of this finding, the present inventors have completed the hole transport body and the photoelectric conversion element of the present disclosure.

Sander Kommeren and five others have reported in Organic Electronics, volume 61, 2018, pp. 282-288 that solar cell properties are maximized by adding an anionic surfactant to an aqueous solution containing a hole transport material.

As a result of detailed studies on effects of a surfactant added to a hole transport body including an organic semiconductor material on the properties of a photoelectric conversion element, the present inventors have found that the capability of drawing charges from a photoelectric conversion layer and the photovoltaic power are improved by using a nonionic surfactant having a critical micelle concentration in a particular range or by using a particular nonionic surfactant and consequently the power conversion efficiency is improved.

### Embodiments of Present Disclosure

Embodiments of the present disclosure will be described hereinafter with reference to the drawings.

### First Embodiment

The hole transport body and the composition of the present disclosure will be described in a first embodiment.

The hole transport body according to the first embodiment includes an organic semiconductor and a nonionic surfactant having a critical micelle concentration of 0.001 g/L or more and 0.080 g/L or less in pure water.

In the hole transport body according to the first embodiment configured as above, interaction between the nonionic surfactant and the organic semiconductor suppresses formation of a three-dimensional higher-order structure. Hence, the hole transport body according to the first embodiment improves, for example, charge transport performance between the hole transport body and another layer (hereinafter referred to as “adjacent layer”) disposed adjacent thereto in a device. Moreover, the present inventors have revealed that the nonionic surfactant having the particular critical micelle concentration is less likely to hinder hole transport in an organic semiconductor. To be more specific, the logarithm of the critical micelle concentration, which is a parameter that is generally easy to estimate experimentally, in pure water linearly correlates to the hydrophile-lipophile-balance (HLB), which is a measure of affinity for water and oil and which is determined by calculation from a molecular structure. Therefore, the critical micelle concentration is a convenient measure of the effectiveness of the nonionic surfactant in a solution, such as a hole transport body solution (namely, a composition for producing the hole transport body according to the first embodiment), containing both a polar molecule and a non-polar molecule. Furthermore, as a result of further studies, the present inventors revealed that, instead of ionic surfactants which commonly have large critical micelle concentrations, nonionic surfactants that can have varying low critical micelle concentrations are suitable for increasing the power conversion efficiency of photoelectric conversion elements. Hence, the hole transport body according to the first embodiment is suitable for increasing the power conversion efficiency of a photoelectric conversion element.

A known organic semiconductor that can transports holes can be used as the organic semiconductor included in the hole transport body according to the first embodiment. Examples of typical organic semiconductors include 2,2′,7,7′-tetrakis[N,N-di-P-methoxyphenylamino]-9,9′-spirobifluorene (hereinafter referred to as “spiro-OMeTAD”), poly[bis(4-phenyl)(2,4,6-triphenylmethyl)amine] (hereinafter referred to as “PTAA”), poly(3-hexylthiophene-2,5-diyl) (hereinafter referred to as “P3HT”), poly(3,4-ethylenedioxythiophene) (hereinafter referred to as “PEDOT”), and copper phthalocyanine (hereinafter referred to as “CuPC”).

The organic semiconductor included in the hole transport body according to the first embodiment may include at least one selected from the group consisting of spiro-OMeTAD, PTAA, P3HT, PEDOT, CuPC, a derivative of spiro-OMeTAD, a derivative of PTAA, a derivative of P3HT, a derivative of PEDOT, and a derivative of CuPC. The hole transport body according to the first embodiment configured as above can further improve the power conversion efficiency of a photoelectric conversion element.

To increase the power conversion efficiency of a photoelectric conversion element including the hole transport body according to the first embodiment, the hole transport body according to the first embodiment may include, for example, any of the following substances as the nonionic surfactant.

The nonionic surfactant may include an alkyl hexyl ether in which the number of carbon atoms in an alkyl group is 1 or more and 5 or less. The alkyl group is, for example, linear. The alkyl hexyl ether may include at least one selected from the group consisting of methyl hexyl ether, ethyl hexyl ether, normal propyl hexyl ether, normal butyl hexyl ether, and normal pentyl hexyl ether.

The nonionic surfactant may include an ester compound obtained by a condensation reaction between a sugar alcohol or an intramolecular dehydration condensation product of a sugar alcohol and a fatty acid.

The above ester compound may include a fatty acid ester in which the number of carbon atoms in the alkyl group is 12 or more and 15 or less.

The above ester compound may include a glycerin fatty acid ester.

The above ester compound may include a sorbitan fatty acid ester.

The above ester compound may include glycerin monolaurate.

The above ester compound may include sorbitan monolaurate.

The above ester compound may include a fatty acid ester of an intramolecular dehydration condensation product of a sugar alcohol, the intramolecular dehydration condensation product being modified with polyethylene glycol.

The polyethylene glycol in the fatty acid ester of the polyethylene glycol-modified intramolecular dehydration condensation product of the sugar alcohol may include 1 or more and 22 or less ethylene glycol units as constituent monomer units. The polyethylene glycol may include, for example, 20 ethylene glycol units as constituent monomer units. The fatty acid ester of the polyethylene glycol-modified intramolecular dehydration condensation product of the sugar alcohol may be a monolaurate, or may be a monooleate.

The nonionic surfactant may include a copolymer of polyethylene glycol and polypropylene glycol. The copolymer may include 6 or more and 53 or less ethylene glycol units and 42 or more and 69 or less propylene glycol units as constituent monomer units. The copolymer is, for example, a block copolymer of ethylene glycol/propylene glycol/ethylene glycol, such as a block copolymer of ethylene glycol pentamer/propylene glycol 68-mer/ethylene glycol pentamer.

The nonionic surfactant may include a glucoside derivative. Herein, the glucoside derivative is, in other words, a molecule including a glucoside. The glucoside derivative may be, for example, an alkyl glucoside derivative. The number of carbon atoms in an alkyl group in the alkyl glucoside derivative is, for example, 6 or more and 12 or less. The alkyl glucoside derivative may be n-octyl-α-D-glucopyranoside.

As described above, the critical micelle concentration of the nonionic surfactant is 0.001 g/L or more and 0.080 g/L or less. In production of a hole transport layer, the nonionic surfactant having such as critical micelle concentration allows the materials in a hole transport solution applied to a photoelectric conversion layer to be dispersed better. Hence, the hole transport body according to the first embodiment can increase the open-circuit voltage and the fill factor of a photoelectric conversion element and improve the power conversion efficiency.

The critical micelle concentration of the nonionic surfactant in pure water can be measured by the following method. For a solution containing pure water and the surfactant dissolved therein, the concentration dependence of a surface tension is determined by a surface tension measurement method, such as the Wilhelmy plate method, and the critical micelle concentration is determined from the surfactant concentration at which the surface tension becomes constant.

In the hole transport body according to the first embodiment, a proportion of the nonionic surfactant may be, for example, 0.5 mass % or more and 36 mass % or less. The hole transport body according to the first embodiment including the nonionic surfactant in this proportion increases the open-circuit voltage and the fill factor of a photoelectric conversion element and thus can further improve the power conversion efficiency.

The hole transport body according to the first embodiment may further include a dopant to dope the organic semiconductor with carriers and improve the hole transport capacity. The dopant increases, for example, the number of holes in the hole transport body. As the dopant, for example, a molecule, such as a salt, that efficiently functions as a dopant may be added.

The dopant may include, for example, at least one selected from the group consisting of lithium hexafluorophosphate, lithium borofluoride, lithium perchlorate, lithium bis(pentafluoroethanesulfonyl)imide, bis(trifluoromethanesulfonyl)amine, lithium bis(trifluoromethanesulfonyl)imide, zinc bis(trifluoromethanesulfonyl)imide, tris[2-(1H-pyrazole-1-yl)-4-tert-butylpyridine]cobalt, 4-isopropyl-4-methyl diphenyl iodonium tetrakis(pentafluorophenyl)borate, tris(pentafluorophenyl)borane, 2,3,5,6-tetrafluoro-7,7,8,8-tetracyano-quinodimethane, and 1,2,3,4,8,9,10,11,15,16, 17, 18,22,23,24,25-hexadecafluoro-29H,31H-phthalocyanine.

The hole transport body according to the first embodiment including any of the above substances as a dopant can further improve the hole transport capacity.

The hole transport body may further include an additive to improve the electrical conductivity. Examples of the additive include a supporting electrolyte and a solvent.

The supporting electrolyte and the solvent stabilize holes in the hole transport body.

Examples of the supporting electrolyte include an ammonium salt, an alkaline earth metal salt, and a transition metal salt. Examples of the ammonium salt include tetrabutylammonium perchlorate, tetraethylammonium hexafluorophosphate, an imidazolium salt, and a pyridinium salt. Examples of the alkali metal salt include lithium perchlorate and potassium tetrafluoroborate. Examples of the alkaline earth metal salt include calcium(II) bis(trifluoromethanesulfonyl)imide. Examples of the transition metal salt include zinc(II) bis(trifluoromethanesulfonyl)imide and tris[4-tert-butyl-2-(1H-pyrazole-1-yl)pyridine]cobalt(III) tris(trifluoromethanesulfonyl)imide.

The solvent included in the hole transport body may be an organic solvent, and may be a hydrophobic organic solvent. To make the solute more stable, the solvent included in the hole transport body may be an organic solvent. Examples of the organic solvent include heterocyclic compound solvents, such as tert-butylpyridine, pyridine, and n-methylpyrrolidone.

For example, a composition according to the first embodiment can be used to produce the hole transport body according to the first embodiment. For example, the hole transport body according to the first embodiment can be formed by an application technique or a printing technique using the composition according to the first embodiment. Examples of the application technique include doctor blade, bar coating, spraying, dip coating, and spin coating. Examples of the printing technique include screen printing.

The composition according to the first embodiment is a composition for producing a hole transport body, and includes an organic semiconductor, a nonionic surfactant, and a solvent.

The organic semiconductor and the nonionic surfactant of the composition according to the first embodiment are respectively the same as the organic semiconductor and the nonionic surfactant of the hole transport body according to the first embodiment. The solvent may be a nonpolar solvent. The solvent may include, for example, at least one selected from the group consisting of toluene and mesitylene. When such a solvent is included, the dispersing effect, which is exhibited in application and drying of a hole transport body solution (namely, the composition according to the first embodiment for producing a hole transport body), of the nonionic surfactant on the materials in the hole transport body solution can be obtained.

The proportion of the nonionic surfactant in the composition according to the first embodiment may be, for example, more than 0 g/L and 1 g/L or less. The proportion of the nonionic surfactant in the composition according to the first embodiment may be more than 0 g/L and 0.2 g/L or less, or may be more than 0 g/L and 0.1 g/L or less. The proportion of the nonionic surfactant in the composition according to the first embodiment may be 0.05 g/L or more and 0.2 g/L or less, or may be 0.05 g/L or more and 0.1 g/L or less. A hole transport body capable of further improving the power conversion efficiency of a photoelectric conversion element can be produced from the composition according to the first embodiment including the nonionic surfactant in such a proportion.

A contact angle of the composition according to the first embodiment on a surface of a glass substrate subjected to UV ozone treatment may be, for example, 7° or more and 30° or less at 24° C. When the composition according to the first embodiment has a small contact angle on such a polar surface, a hole transport body formed using the composition according to the first embodiment is in closer contact with a photoelectric conversion layer to increase the open-circuit voltage and the fill factor of a photoelectric conversion element, and thus can further increase the power conversion efficiency. Moreover, the solution is applied more smoothly to and adheres better to the photoelectric conversion layer, and a higher yield is achieved in an area increasing step.

The contact angle of the composition according to the first embodiment can be measured by the following method. A glass substrate is subjected to UV ozone treatment, a drop of the composition according to the first embodiment is put on a surface of the glass substrate with a micropipette, and the drop is observed, for example, with a CCD camera to measure the contact angle. For example, FAMAS (manufactured by Kyowa Interface Science Co., Ltd.) may be used for contact angle measurement.

### Second Embodiment

In a second embodiment, the hole transport body and the composition of the present disclosure will be described.

A hole transport body according to the second embodiment includes an organic semiconductor and a nonionic surfactant.

The above nonionic surfactant includes an alkyl hexyl ether in which the number of carbon atoms in an alkyl group is 1 or more and 5 or less. The alkyl group is, for example, linear. The alkyl hexyl ether may include at least one selected from the group consisting of methyl hexyl ether, ethyl hexyl ether, normal propyl hexyl ether, normal butyl hexyl ether, and normal pentyl hexyl ether.

In the hole transport body according to the second embodiment configured as above, formation of a three-dimensional higher-order structure is suppressed by interaction between the nonionic surfactant and the organic semiconductor. Hence, the hole transport body according to the second embodiment improves, for example, charge transport performance between the hole transport body and its adjacent layer disposed adjacent thereto in a device.

Any of the materials shown as examples of the organic semiconductor included in the hole transport body in the first embodiment can be used as the organic semiconductor included in the hole transport body according to the second embodiment.

In the hole transport body according to the second embodiment, a proportion of the nonionic surfactant may be, for example, 0.5 mass % or more and 36 mass % or less. The hole transport body according to the second embodiment including the nonionic surfactant in this proportion increases the open-circuit voltage and the fill factor of a photoelectric conversion element and can further improve the power conversion efficiency.

The hole transport body according to the second embodiment may further include a dopant to dope the organic semiconductor with carriers and improve the hole transport capacity. The dopant increases, for example, the number of holes in the hole transport body. As the dopant, for example, a molecule, such as a salt, that efficiently functions as a dopant may be added.

Any of the materials shown as examples of the dopant included in the hole transport body in the first embodiment can be used as the dopant included in the hole transport body according to the second embodiment.

The hole transport body according to the second embodiment may further include an additive to improve the electrical conductivity. The additive is, for example, a supporting electrolyte or a solvent, and the materials shown as examples of the supporting electrolyte or the solvent included in the hole transport body in the first embodiment can be used.

For example, a composition according to the second embodiment can be used to produce the hole transport body according to the second embodiment. For example, the hole transport body according to the second embodiment can be formed by a coating technique or a printing technique using the composition according to the second embodiment. Examples of the coating technique include doctor blade, bar coating, spraying, dip coating, and spin coating. Examples of the printing technique include screen printing.

The composition according to the second embodiment is a composition for producing a hole transport body, and includes an organic semiconductor, a nonionic surfactant, and a solvent.

The organic semiconductor and the nonionic surfactant of the composition according to the second embodiment are respectively the same as the organic semiconductor and the nonionic surfactant of the hole transport body according to the second embodiment. The solvent may be a nonpolar solvent. The solvent may include, for example, at least one selected from the group consisting of toluene and mesitylene. When such a solvent is included, the dispersing effect, which is exhibited in application and drying of a hole transport body solution (namely, the composition according to the second embodiment for producing a hole transport body), of the nonionic surfactant on the materials in the hole transport body solution can be obtained.

The proportion of the nonionic surfactant in the composition according to the second embodiment may be, for example, more than 0 g/L and 1 g/L or less. The proportion of the nonionic surfactant in the composition according to the second embodiment may be more than 0 g/L and 0.2 g/L or less, or may be more than 0 g/L and 0.1 g/L or less. The proportion of the nonionic surfactant in the composition according to the second embodiment may be 0.05 g/L or more and 0.2 g/L or less, or may be 0.05 g/L or more and 0.1 g/L or less. When the nonionic surfactant is included in such a proportion, a hole transport body capable of further improving the power conversion efficiency of a photoelectric conversion element can be produced from the composition according to the second embodiment.

A contact angle of the composition according to the second embodiment on a surface of a glass substrate subjected to UV ozone treatment may be, for example, 7° or more and 30° or less at 24° C. When the composition according to the second embodiment has a small contact angle on such a polar surface, a hole transport body formed using the composition according to the second embodiment is in closer contact with a photoelectric conversion layer to increase the open-circuit voltage and the fill factor of a photoelectric conversion element, and thus can further increase the power conversion efficiency. Moreover, the solution is applied more smoothly to and adheres better to the photoelectric conversion layer, and a higher yield is achieved in an area increasing step.

The above contact angle of the composition according to the second embodiment can be measured by the same method as that for measuring the contact angle of the composition according to the first embodiment.

### Third Embodiment

The photoelectric conversion element of the present disclosure will be described as a third embodiment.

A photoelectric conversion element according to the third embodiment includes a first electrode, a photoelectric conversion layer, a hole transport layer, and a second electrode. The photoelectric conversion element according to the third embodiment may include, for example, the first electrode, the photoelectric conversion layer, the hole transport layer, and the second electrode in this order. The hole transport layer may include the hole transport body according to the first embodiment or the second embodiment.

Since including the hole transport body according to first embodiment or the second embodiment, the photoelectric conversion element according to the third embodiment has high power conversion efficiency.

The photoelectric conversion element according to the third embodiment can be used, for example, as a solar cell.

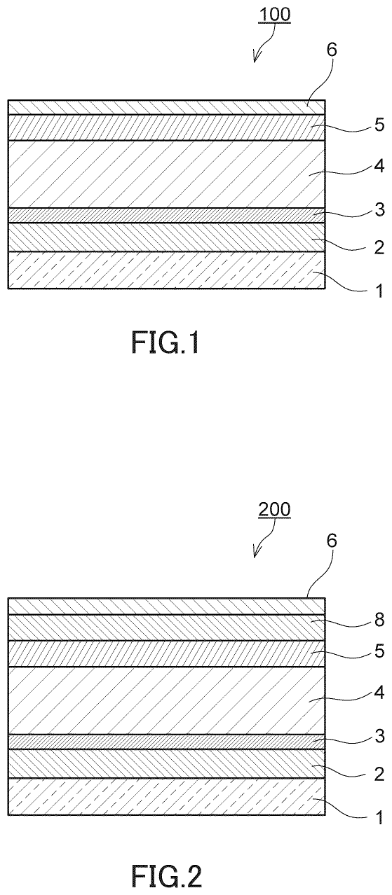

FIG. 1 is a cross-sectional view showing the photoelectric conversion element according to the third embodiment. A photoelectric conversion element 100 shown in FIG. 1 is an examples of the configuration of the photoelectric conversion element according to the third embodiment.

The photoelectric conversion element 100 includes a substrate 1, a first electrode 2, an electron transport layer 3, a photoelectric conversion layer 4, a hole transport layer 5, and a second electrode 6 in this order.

The photoelectric conversion element 100 may be free of the electron transport layer 3.

Upon irradiation of the photoelectric conversion element 100 with light, the photoelectric conversion layer 4 absorbs the light to produce excited electrons and holes. The excited electrons transfer to the first electrode 2 through the electron transport layer 3. On the other hand, the holes formed in the photoelectric conversion layer 4 transfer to the second electrode 6 through the hole transport layer 5. The photoelectric conversion element 100 can thereby draw out an electric current from the first electrode 2 as a negative electrode and the second electrode 6 as a positive electrode.

The photoelectric conversion element 100 can be produced, for example, by the following method.

First, the first electrode 2 is formed on a surface of the substrate 1 by chemical vapor deposition, sputtering, or the like. Next, the electron transport layer 3 is formed thereon by chemical vapor deposition, sputtering, solution coating, or the like. Subsequently, the photoelectric conversion layer 4 is formed on the electron transport layer 3. For example, a perovskite compound may be cut to a given thickness to obtain the photoelectric conversion layer 4, which may be then disposed on the electron transport layer 3. Next, the hole transport layer 5 is formed on the photoelectric conversion layer 4 by chemical vapor deposition, sputtering, solution coating, or the like. Then, the second electrode 6 is formed on the hole transport layer 5 by chemical vapor deposition, sputtering, solution coating, or the like. The photoelectric conversion element 100 can be obtained in the above manner.

The photoelectric conversion element 100 according to the third embodiment may further include, as a second hole transport layer, a hole transport layer different from the hole transport layer 5. FIG. 2 is a cross-sectional view showing a first modification of the photoelectric conversion element according to the third embodiment. A second hole transport layer 8 is disposed between the hole transport layer 5 and the second electrode 6.

A photoelectric conversion element 200 of the first modification according to the third embodiment includes the substrate 1, the first electrode 2, the electron transport layer 3, the photoelectric conversion layer 4, the hole transport layer 5, the second hole transport layer 8, and the second electrode 6 in this order.

The photoelectric conversion element 200 may be free of the electron transport layer 3.

The photoelectric conversion element 100 according to the third embodiment may further include a porous layer. The porous layer is disposed, for example, between the electron transport layer and the photoelectric conversion layer.

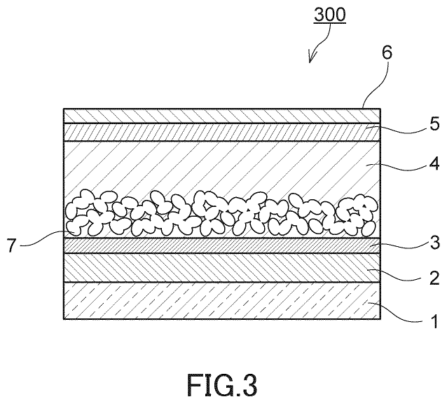

FIG. 3 is a cross-sectional view showing a second modification of the photoelectric conversion element according to the third embodiment.

A photoelectric conversion element 300 of the second modification according to the third embodiment includes the substrate 1, the first electrode 2, the electron transport layer 3, a porous layer 7, the photoelectric conversion layer 4, the hole transport layer 5, and the second electrode 6 in this order.

The porous layer 7 includes a porous body. The porous body includes a pore.

The photoelectric conversion element 200 and the photoelectric conversion element 300 may be free of the electron transport layer 3.

The components of the photoelectric conversion element will be specifically described hereinafter.

### (Substrate 1)

The substrate 1 is an accessory component. The substrate 1 supports the layers in the photoelectric conversion element. The substrate 1 can be formed using a transparent material. A glass substrate or a plastic substrate, for example, can be used as the substrate 1. The plastic substrate may be, for example, a plastic film.

When the second electrode 6 has a light-transmitting property, the substrate 1 may be formed of a material not having a light-transmitting property. As the material can be used a metal, a ceramic, or a resin material having a low light-transmitting property.

When the first electrode 2 is strong enough to support the layers, the substrate 1 may be omitted.

### (First Electrode 2)

The first electrode 2 has electrical conductivity. The first electrode 2 has a light-transmitting property. For example, the first electrode 2 allows visible to near-infrared light to pass therethrough.

The first electrode 2 is formed of, for example, a transparent and electrically conductive material. The material is, for example, a metal oxide or a metal nitride. The material is, for example,
(i) titanium oxide doped with at least one selected from the group consisting of lithium, magnesium, niobium, and fluorine,
(ii) gallium oxide doped with at least one selected from the group consisting of tin and silicon,
(iii) gallium nitride doped with at least one selected from the group consisting of silicon and oxygen,
(iv) tin oxide doped with at least one selected from the group consisting of antimony and fluorine,
(v) zinc oxide doped with at least one selected from the group consisting of boron, aluminum, gallium, and indium,
(vi) indium-tin composite oxide, or
(vii) a composite thereof.

The first electrode 2 may be formed using a non-transparent material to have a pattern that allows light to pass therethrough. The pattern that allows light to pass therethrough is, for example, a linear pattern, a wave line pattern, a lattice pattern, or a perforated-metal-like pattern where a lot of small through holes are regularly or irregularly arranged. When the first electrode 2 has any of these patterns, light can pass through the portions free of the electrode material. Examples of the non-transparent electrode material include platinum, gold, silver, copper, aluminum, rhodium, indium, titanium, iron, nickel, tin, zinc, or an alloy including any of these. An electrically conductive carbon material may be used as the non-transparent electrode material.

When the photoelectric conversion element does not include the electron transport layer 3, the first electrode 2 has a property of blocking holes from the photoelectric conversion layer 4. In this case, the first electrode 2 is not in ohmic contact with the photoelectric conversion layer 4. The property of blocking holes from the photoelectric conversion layer 4 is a property of allowing only electrons formed in the photoelectric conversion layer 4 to pass and not allowing holes to pass. The Fermi energy level of a material having such a property is higher than the energy level of the photoelectric conversion layer 4 at an upper part of the valence band. The Fermi energy level of a material having such a property may be higher than the Fermi energy level of the photoelectric conversion layer 4. The material is specifically, for example, aluminum.

When the photoelectric conversion element includes the electron transport layer 3, the first electrode 2 does not necessarily have the property of blocking holes from the photoelectric conversion layer 4. In this case, the first electrode 2 can be formed of a material capable of forming an ohmic contact with the photoelectric conversion layer 4. In this case, the first electrode 2 may be in ohmic contact with the photoelectric conversion layer 4, or is not necessarily in ohmic contact with the photoelectric conversion layer 4.

The transmittance of the first electrode 2 may be, for example, 50% or more, or may be 80% or more. The wavelength of light that is to pass through the first electrode 2 depends on the absorption wavelength of the photoelectric conversion layer 4.

The thickness of the first electrode 2 may be, for example, 1 nm or more and 1000 nm or less.

### (Electron Transport Layer 3)

The electron transport layer 3 includes a semiconductor. The electron transport layer 3 may be formed of a semiconductor having a band gap of 3.0 eV or more. In this case, the electron transport layer 3 allows visible light and infrared light to pass therethrough to the photoelectric conversion layer 4. The semiconductor is, for example, an inorganic n-type semiconductor.

Examples of the inorganic n-type semiconductor include a metal oxide, a metal nitride, and a perovskite oxide. The metal oxide is, for example, an oxide of Cd, Zn, In, Pb, Mo, W, Sb, Bi, Cu, Hg, Ti, Ag, Mn, Fe, V, Sn, Zr, Sr, Ga, Si, or Cr. The metal oxide is, for example, TiO₂ or SnO₂. The metal nitride is, for example, GaN. The perovskite oxide is, for example, SrTiO₃ or CaTiO₃.

The electron transport layer 3 may include a substance having a band gap of more than 6.0 eV. Examples of the substance having a band gap of more than 6.0 eV include:
(i) halides, such as lithium fluoride and calcium fluoride, of alkali metals and alkaline earth metals;
(ii) alkali metal oxides, such as magnesium oxide; and
(iii) silicon dioxide. In this case, the electron transport layer 3 may have a thickness of, for example, 10 nm or less to secure the electron transport capability.

The electron transport layer 3 may include a plurality of layers formed of different materials.

### (Photoelectric Conversion Layer 4)

The photoelectric conversion layer 4 includes a photoelectric conversion material. The photoelectric conversion material may be, for example, a perovskite compound. That is, the photoelectric conversion layer 4 may include a perovskite compound. Perovskite compounds have a high light absorption coefficient in a wavelength range of a solar spectrum and have high carrier mobility. Hence, photoelectric conversion elements including a perovskite compound have high power conversion efficiency.

The perovskite compound is represented, for example, by a composition formula ABX₃. The symbol A is a monovalent cation. Examples of the monovalent cation include an alkali metal cation or an organic cation. Examples of the alkali metal cation include a potassium cation (K⁺), a cesium cation (Cs⁺), and a rubidium cation (Rb⁺). Examples of the organic cation include a methylammonium cation (CH₃NH₃⁺), a formamidinium cation (HC(NH₂)₂⁺), an ethylammonium cation (CH₃CH₂NH₃⁺), and a guanidinium cation (CH₆N₃⁺). The symbol B is a divalent cation. Examples of the divalent cation include a Sn cation (Sn²⁺), a Ge cation (Ge²⁺), and a Pb cation (Pb²⁺). The divalent cation may include at least one selected from the group consisting of a Sn cation, a Ge cation, and a Pb cation. The symbol X is a monovalent anion. Examples of the monovalent anion include a halogen anion. The sites of A may be occupied by different ions, and so may the sites of B and the sites of X.

The photoelectric conversion layer 4 has a thickness of, for example, 50 nm or more and 10 μm or less.

The photoelectric conversion layer 4 is formed, for example, by a coating technique involving a solution, a printing technique, or a deposition technique. The photoelectric conversion layer 4 may be formed by cutting a perovskite compound.

The photoelectric conversion layer 4 may include the perovskite compound represented by the composition formula ABX₃ as its main component. Saying that “the photoelectric conversion layer 4 includes the perovskite compound represented by the composition formula ABX₃ as its main component” herein means that the perovskite compound represented by the composition formula ABX₃ accounts for 90 mass % or more of the photoelectric conversion layer 4. The perovskite compound represented by the composition formula ABX₃ may account for 95 mass % or more of the photoelectric conversion layer. The photoelectric conversion layer 4 may consist of the perovskite compound represented by the composition formula ABX₃. The photoelectric conversion layer 4 is required to include the perovskite compound represented by the composition formula ABX₃, and may include a defect or an impurity.

The photoelectric conversion layer 4 may further include an additional compound different from the perovskite compound represented by the composition formula ABX₃. Examples of the additional compound include compounds having a Ruddlesden-Popper layered perovskite structure.

### (Hole Transport Layer 5)

As described above, the hole transport layer 5 includes the hole transport body according to the first embodiment or the second embodiment. The hole transport layer 5 may be formed of the hole transport body according to the first embodiment or the second embodiment.

The hole transport layer 5 may include a plurality of layers formed of different materials. For example, hole transport properties of the hole transport layer 5 are improved by stacking the plurality of layers whose ionization potentials are smaller than that of the photoelectric conversion layer 4 such that the ionization potentials decrease layer by layer with increasing distance from the photoelectric conversion layer 4.

The thickness of the hole transport layer 5 may be 1 nm or more and 1000 nm or less, or 10 nm or more and 50 nm or less. In this case, sufficiently high hole transport properties can be exhibited and a low resistance can be maintained; hence, high power conversion efficiency can be achieved.

The hole transport layer 5 is formed, for example, by a coating technique, a printing technique, or a deposition technique. The same can be said to the photoelectric conversion layer 4. Examples of the coating technique include doctor blade, bar coating, spraying, dip coating, and spin coating. Examples of the printing technique include screen printing. If needed, the hole transport layer 5 may be formed using a mixture of a plurality of materials and then compressed or fired.

### (Second Electrode 6)

The first electrode 6 has electrical conductivity. Since the photoelectric conversion element according to the third embodiment includes the hole transport layer 5, the second electrode 6 does not necessarily have the property of blocking electrons from the photoelectric conversion layer 4. That is, the material of the second electrode 6 may be a material capable of forming an ohmic contact with the photoelectric conversion layer 4. Therefore, the second electrode 6 can be formed to have a light-transmitting property. An electrode that is the first electrode 2 or the second electrode 6 and that is configured to allow light to be incident thereon is required to have a light-transmitting property. That is, either the first electrode 2 or the second electrode 6 does not necessarily have a light-transmitting property. That is, either of the first electrode 2 or the second electrode 6 does not necessarily include a material having a light-transmitting property, or does not necessarily have a pattern including an opening portion that allows light to pass therethrough.

When the second electrode 6 is an electrode having a light-transmitting property, the second electrode 6 can allow visible to near-infrared light to pass therethrough. The electrode having a light-transmitting property can be formed of a transparent and electrically conductive material.

The material is, for example,
(i) titanium oxide doped with at least one selected from the group consisting of lithium, magnesium, niobium, and fluorine,
(ii) gallium oxide doped with at least one selected from the group consisting of tin and silicon,
(iii) gallium nitride doped with at least one selected from the group consisting of silicon and oxygen,
(iv) indium-tin composite oxide,
(v) tin oxide doped with at least one selected from the group consisting of antimony and fluorine,
(vi) zinc oxide doped with at least one selected from the group consisting of boron, aluminum, gallium, and indium, or
(vii) a composite thereof.

The electrode having a light-transmitting property can be formed using a non-transparent material to have a pattern that allows light to pass therethrough. The pattern that allows light to pass therethrough is, for example, a linear pattern, a wave line pattern, a lattice pattern, or a perforated-metal-like pattern where a lot of small through holes are regularly or irregularly arranged. When the electrode having a light-transmitting property has any of these patterns, light can pass through the portions free of the electrode material. Examples of the non-transparent material include platinum, gold, silver, copper, aluminum, rhodium, indium, titanium, iron, nickel, tin, zinc, and alloys including any of these. An electrically conductive carbon material may be used as the non-transparent material.

The transmittance of the second electrode 6 may be 50% or more, or 80% or more. The wavelength of light that passes through the second electrode 6 depends on the absorption wavelength of the photoelectric conversion layer 4. The thickness of the first electrode 6 is, for example, 2 nm or more and 1000 nm or less.

### (Second Hole Transport Layer 8)

The second hole transport layer 8 includes a hole transport material. The second hole transport layer 8 is formed on the hole transport layer 5, for example, by vacuum deposition.

The second hole transport layer 8 may be an inorganic p-type semiconductor. Examples of the inorganic semiconductor include Cu₂O, CuGaO₂, CuSCN, CuI, NiOₓ, MoOₓ, V₂O₅, and carbon materials, such as graphene oxide.

In the case where the inorganic semiconductor is selected as the second hole transport layer 8 and the hole transport layer 5 is an organic semiconductor, damage to the hole transport layer 5 in formation of the second electrode 6 can be reduced. Moreover, in this case, a short circuit due to a gap in the hole transport layer 5 can be prevented.

The second hole transport layer 8 may include at least one selected from the group consisting of tungsten oxide and molybdenum oxide. The second hole transport layer 8 including at least one selected from the group consisting of tungsten oxide and molybdenum oxide can more reliably prevent a short circuit due to a gap in the hole transport layer 5 and also has an excellent hole transport capability. Hence, the photoelectric conversion element 200 including the second hole transport layer 8 configured as above can achieve a higher voltage.

To increase the voltage of the photoelectric conversion element 200, the second hole transport layer 8 may have a thickness of 5 nm or more and 40 nm or less. Desirably, the second hole transport layer 8 may have a thickness of 5 nm or more and 30 nm or less.

### (Porous Layer 7)

The porous layer 7 is formed on the electron transport layer 3, for example, by a coating technique. In the case where the photoelectric conversion element does not include the electron transport layer 3, the porous layer 7 is formed on the first electrode 2.

A pore structure provided by the porous layer 7 serves as a foundation at the time of formation of the photoelectric conversion layer 4. The porous layer 7 does not hinder light absorption by the photoelectric conversion layer 4 and electron transfer from the photoelectric conversion layer 4 to the electron transport layer 3.

The porous layer 7 includes a porous body.

The porous body is formed of, for example, continuous insulating particles or continuous semiconductor particles. The insulating particles are, for example, aluminum oxide particles or silicon oxide particles. The semiconductor particles are, for example, inorganic semiconductor particles. The inorganic semiconductor is, for example, a metal oxide, a perovskite oxide of a metal element, a sulfide of a metal element, or a metal chalcogenide. The metal oxide is, for example, an oxide of Cd, Zn, In, Pb, Mo, W, Sb, Bi, Cu, Hg, Ti, Ag, Mn, Fe, V, Sn, Zr, Sr, Ga, Si, or Cr. The metal oxide is, for example, TiO₂. The perovskite oxide of a metal element is, for example, SrTiO₃ or CaTiO₃. The sulfide of a metal element is, for example, CdS, ZnS, In₂S₃, PbS, MozS, WS₂, Sb₂S₃, Bi₂S₃, ZnCdS₂, or Cu₂S. The metal chalcogenide is, for example, CsSe, In₂Se₃, WSe₂, HgS, PbSe, or CdTe.

The thickness of the porous layer 7 may be 0.01 μm or more and 10 μm or less, or 0.05 μm or more and 1 μm or less.

Regarding surface roughness of the porous layer 7, a surface roughness factor determined by “effective area/projected area” may be 10 or greater, or 100 or greater. The projected area refers to the area of a shadow behind an object irradiated with light from the front. The effective area refers to the actual surface area of an object. The effective area can be calculated from a volume of an object, the specific surface area of the material of the object, and the bulk density of the material of the object, the volume being determined from the projected area and the thickness of the object. The specific surface area is measured, for example, by a nitrogen adsorption method.

The pore in the porous layer 7 is continuous from a portion of the porous layer 7 in contact with the photoelectric conversion layer 4 to a portion of the porous layer 7 in contact with the electron transport layer 3. That is, the pore in the porous layer 7 is continuous from one principal surface of the porous layer 7 to the other principal surface thereof. This allows the material of the photoelectric conversion layer 4 to fill the pore of the porous layer 7 and reach the surface of the electron transport layer 3. The photoelectric conversion layer 4 and the electron transport layer 3 are thus in direct contact with each other and therefore can exchange electrons therebetween.

Provision of the porous layer makes it easy to form the photoelectric conversion layer 4. When the porous layer 7 is provided, the material of the photoelectric conversion layer 4 enters the pore of the porous layer 7, which then serves as a foothold for the photoelectric conversion layer 4. This makes it less likely that the material of the photoelectric conversion layer 4 is repelled by the surface of the porous layer 7 or aggregates on the surface of the porous layer 7. Hence, the photoelectric conversion layer 4 can be easily formed as a uniform film. The photoelectric conversion layer 4 is formed, for example, by a coating technique, a printing technique, or a deposition technique.

The porous layer 7 may increase the optical path length of light passing through the photoelectric conversion layer 4 by causing light scattering. The amount of electrons and holes formed in the photoelectric conversion layer 4 is expected to increase with the increase of the optical path length.

### (Function and Effect of Photoelectric Conversion Element)

Next, a basic function and effect of the photoelectric conversion element 100 will be described. In the photoelectric conversion element 100, at least one selected from the group consisting of the substrate 1 and the second electrode 6 has a light-transmitting property. Light is incident on the photoelectric conversion element 100 through a surface thereof having a light-transmitting property. Upon irradiation of the photoelectric conversion element 100 with light, the photoelectric conversion layer 4 absorbs the light to produce excited electrons and holes. The excited electrons transfer to the electron transport layer 3. On the other hand, the holes formed in the photoelectric conversion layer 4 transfer to the hole transport layer 5. The electron transport layer 3 and the hole transport layer 5 are electrically connected to the first electrode 2 and the second electrode 6, respectively. An electric current is drawn out from the first electrode 2 and the second electrode 6 that function, respectively, as a negative electrode and a positive electrode. The hole transport layer 5 and the electron transport layer 3 can be reversed with respect to the light incident direction. The photoelectric conversion element 200 of the first modification and the photoelectric conversion element 300 of the second modification also have a similar function and effect.

### Other Embodiments

### (Supplement)

According to the description of the above embodiments, the following techniques are disclosed.

### (Technique 1)

A hole transport body including:
an organic semiconductor; and
a nonionic surfactant having a critical micelle concentration of 0.001 g/L or more and 0.080 g/L or less in pure water.

The hole transport body of Technique 1 configured as above can improve the power conversion efficiency of a photoelectric conversion material.

### (Technique 2)

The hole transport body according to Technique 1, further including a dopant. The hole transport body of Technique 2 configured as above can improve the hole transport capacity.

### (Technique 3)

The hole transport body of Technique 1 or 2, wherein the nonionic surfactant includes an alkyl hexyl ether in which the number of carbon atoms in an alkyl group is 1 or more and 5 or less.

The hole transport body of Technique 3 configured as above can further improve the power conversion efficiency of a photoelectric conversion material.

### (Technique 4)

The hole transport body of Technique 3, wherein the alkyl hexyl ether includes at least one selected from the group consisting of methyl hexyl ether, ethyl hexyl ether, normal propyl hexyl ether, normal butyl hexyl ether, and normal pentyl hexyl ether.

The hole transport body of Technique 4 configured as above can further improve the power conversion efficiency of a photoelectric conversion material.

### (Technique 5)

The hole transport body according to any one of Techniques 1 to 4, wherein the nonionic surfactant includes an ester compound obtained by a condensation reaction between a sugar alcohol or an intramolecular dehydration condensation product of a sugar alcohol and a fatty acid.

The hole transport body of Technique 5 configured as above can further improve the power conversion efficiency of a photoelectric conversion material.

### (Technique 6)

The hole transport body of Technique 5, wherein the ester compound includes a fatty acid ester in which the number of carbon atoms in an alkyl group is 12 or more and 15 or less.

The hole transport body of Technique 6 configured as above can further improve the power conversion efficiency of a photoelectric conversion material.

### (Technique 7)

The hole transport body of Technique 5 or 6, wherein the ester compound includes a glycerin fatty acid ester.

The hole transport body of Technique 7 configured as above can further improve the power conversion efficiency of a photoelectric conversion material.

### (Technique 8)

The hole transport body according to any one of Techniques 5 to 7, wherein the ester compound includes a sorbitan fatty acid ester.

The hole transport body of Technique 8 configured as above can further improve the power conversion efficiency of a photoelectric conversion material.

### (Technique 9)

The hole transport body according to Technique 8, wherein the ester compound includes glycerin monolaurate.

The hole transport body of Technique 9 configured as above can further improve the power conversion efficiency of a photoelectric conversion material.

### (Technique 10)

The hole transport body according to any one of Techniques 5 to 9, wherein the ester compound includes a fatty acid ester of an intramolecular dehydration condensation product of a sugar alcohol, the intramolecular dehydration condensation being modified with polyethylene glycol.

The hole transport body of Technique 10 configured as above can further improve the power conversion efficiency of a photoelectric conversion material.

### (Technique 11)

The hole transport body of Technique 10, wherein the polyethylene glycol includes 1 or more and 22 or less ethylene glycol units as constituent monomer units.

The hole transport body of Technique 11 configured as above can further improve the power conversion efficiency of a photoelectric conversion material.

### (Technique 12)

The hole transport body of Technique 10 or 11, wherein the fatty acid ester of the intramolecular dehydration condensation product of the sugar alcohol includes a monolaurate.

The hole transport body of Technique 12 configured as above can further improve the power conversion efficiency of a photoelectric conversion material.

### (Technique 13)

The hole transport body according to any one of Techniques 10 to 12, wherein the fatty acid ester of the intramolecular dehydration condensation product of the sugar alcohol includes a monooleate.

The hole transport body of Technique 13 configured as above can further improve the power conversion efficiency of a photoelectric conversion material.

### (Technique 14)

The hole transport body according to any one of Techniques 1 to 13, wherein the nonionic surfactant includes a copolymer of polyethylene glycol and polypropylene glycol.

The hole transport body of Technique 14 configured as above can further improve the power conversion efficiency of a photoelectric conversion material.

### (Technique 15)

The hole transport body of Technique 14, wherein the copolymer includes 6 or more and 53 or less ethylene glycol units and 42 or more and 69 or less propylene glycol units as constituent monomer units.

The hole transport body of Technique 15 configured as above can further improve the power conversion efficiency of a photoelectric conversion material.

### (Technique 16)

The hole transport body according to any one of Techniques 1 to 15, wherein the nonionic surfactant includes a glucoside derivative.

The hole transport body of Technique 16 configured as above can further improve the power conversion efficiency of a photoelectric conversion material.

### (Technique 17)

The hole transport body of Technique 16, wherein the glucoside derivative is an alkyl glucoside derivative.

The hole transport body of Technique 17 configured as above can further improve the power conversion efficiency of a photoelectric conversion material.

### (Technique 18)

The hole transport body of Technique 17, wherein the alkyl glucoside derivative is n-octyl-α-D-glucopyranoside.

The hole transport body of Technique 18 configured as above can further improve the power conversion efficiency of a photoelectric conversion material.

### (Technique 19)

The hole transport body according to any one of Techniques 1 to 18, wherein the organic semiconductor includes at least one selected from the group consisting of 2,2′,7,7′-tetrakis[N,N-di-P-methoxyphenylamino]-9,9′-spirobifluorene, poly[bis(4-phenyl) (2,4,6-triphenylmethyl)amine], poly(3-hexylthiophene-2,5-diyl), poly(3,4-ethylenedioxythiophene), copper phthalocyanine, a derivative of 2,2′,7,7′-tetrakis[N,N-di-P-methoxyphenylamino]-9,9′-spirobifluorene, a derivative of poly[bis(4-phenyl)(2,4,6-triphenylmethyl)amine], a derivative of poly(3-hexylthiophene-2,5-diyl), a derivative of poly(3,4-ethylenedioxythiophene), and a derivative of copper phthalocyanine.

The hole transport body of Technique 19 configured as above can further improve the power conversion efficiency of a photoelectric conversion material.

### (Technique 20)

The hole transport body of Technique 2, wherein the dopant includes at least one selected from the group consisting of lithium hexafluorophosphate, lithium borofluoride, lithium perchlorate, lithium bis(pentafluoroethanesulfonyl)imide, bis(trifluoromethanesulfonyl)amine, lithium bis(trifluoromethanesulfonyl)imide, zinc bis(trifluoromethanesulfonyl)imide, tris[2-(1H-pyrazole-1-yl)-4-tert-butylpyridine]cobalt, 4-isopropyl-4-methyl diphenyl iodonium tetrakis(pentafluorophenyl)borate, tris(pentafluorophenyl)borane, 2,3,5,6-tetrafluoro-7,7,8,8-tetracyano-quinodimethane, and 1,2,3,4,8,9,10,11,15,16,17,18,22,23,24,25-hexadecafluoro-29H,31H-phthalocyanine.

The hole transport body of Technique 20 configured as above can further improve the hole transport capacity.

### (Technique 21)

The hole transport body according to any one of Techniques 1 to 20, wherein a proportion of the nonionic surfactant is 0.5 mass % or more and 36 mass % or less.

The hole transport body of Technique 21 configured as above can further improve the power conversion efficiency of a photoelectric conversion material.

### (Technique 22)

A hole transport body including:
an organic semiconductor; and
a nonionic surfactant, wherein
the nonionic surfactant includes an alkyl hexyl ether in which the number of carbon atoms in an alkyl group is 1 or more and 5 or less.

The hole transport body of Technique 22 configured as above can improve the power conversion efficiency of a photoelectric conversion material.

### (Technique 23)

The hole transport body of Technique 22, wherein the alkyl hexyl ether includes at least one selected from the group consisting of methyl hexyl ether, ethyl hexyl ether, normal propyl hexyl ether, normal butyl hexyl ether, and normal pentyl hexyl ether.

The hole transport body of Technique 23 configured as above can further improve the power conversion efficiency of a photoelectric conversion material.

### (Technique 24)

A photoelectric conversion element including: a first electrode; a hole transport layer; a photoelectric conversion layer; and a second electrode, wherein the hole transport layer includes the hole transport body according to any one of Techniques 1 to 23.

The photoelectric conversion element of Technique 24 configured as above can achieve high power conversion efficiency.

### (Technique 25)

The photoelectric conversion element according to Technique 24, wherein the photoelectric conversion layer includes a perovskite compound.

The photoelectric conversion element of Technique 25 configured as above can achieve high power conversion efficiency.

### (Technique 26)

The photoelectric conversion element of Technique 25, wherein
the perovskite compound is composed of a monovalent cation, a divalent cation, and a halogen anion, and
the divalent cation includes at least one selected from the group consisting of a Sn cation, a Ge cation, and a Pb cation.

The photoelectric conversion element of Technique 24 configured as above can achieve high power conversion efficiency.

### (Technique 27)

A composition for producing a hole transport body, the composition including:
an organic semiconductor;
a nonionic surfactant having a critical micelle concentration of 0.001 g/L or more and 0.080 g/L or less in pure water; and
a solvent.

A hole transport body capable of improving the power conversion efficiency of a photoelectric conversion element can be produced using the composition of Technique 27 configured as above.

### (Technique 28)

The composition according to Technique 27, wherein a proportion of the nonionic surfactant in the composition is more than 0 g/L and 1 g/L or less.

A hole transport body capable of improving the power conversion efficiency of a photoelectric conversion element can be produced using the composition of Technique 28 configured as above.

### (Technique 29)

The composition of Technique 27 or 28, wherein a contact angle of the composition on a surface of glass subjected to UV ozone treatment is 7° or more and 30° or less at 24° C.

A hole transport body capable of improving the power conversion efficiency of a photoelectric conversion element can be produced using the composition of Technique 29 configured as above.

### (Technique 30)

A composition for producing a hole transport body, the composition including:
an organic semiconductor;
a nonionic surfactant; and
a solvent, wherein
the nonionic surfactant includes an alkyl hexyl ether in which the number of carbon atoms in an alkyl group is 1 or more and 5 or less.

A hole transport body capable of improving the power conversion efficiency of a photoelectric conversion element can be produced using the composition of Technique 30 configured as above.

### (Technique 31)

The composition according to Technique 30, wherein the alkyl hexyl ether includes at least one selected from the group consisting of methyl hexyl ether, ethyl hexyl ether, normal propyl hexyl ether, normal butyl hexyl ether, and normal pentyl hexyl ether.

A hole transport body capable of further improving the power conversion efficiency of a photoelectric conversion element can be produced using the composition of Technique 31 configured as above.

### EXAMPLES

The present disclosure will be described hereinafter in more details with reference to Examples and Comparative Examples.

In each of Examples and Comparative Examples, a solar cell including a photoelectric conversion layer including a hole transport layer formed of an organic semiconductor film and a perovskite compound was produced as a photoelectric conversion element. Initial property evaluation, light resistance evaluation, and thermal resistance evaluation were performed for the solar cells of Examples and Comparative Examples.

The configurations of the solar cells of Examples 1 to 7 and Comparative Examples 1 and 2 are as follows. That is, solar cells having the same structure as that of the photoelectric conversion element 200 shown in FIG. 2 were produced.
Substrate 1: A glass substrate (thickness: 0.7 mm).
First electrode 2: A transparent conductive layer, which is an indium-tin composite oxide layer (thickness: 100 nm)·
Electron transport layer 3: A tin oxide (SnO₂) (thickness: 30 nm)·
Photoelectric conversion layer 4: A layer chiefly including Rb_{0.03}Cs_{0.06}MA_{0.16}FA_{0.75}Pb_{12.85}Br_{0.15} (thickness: 400 nm) (MA: CH₃NH₃; FA: HC(NH₂)₂).
Hole transport layer 5: A layer chiefly including PTAA (and including lithium bis(trifluoromethanesulfonyl)imide (manufactured by Tokyo Chemical Industry Co., Ltd.) as a dopant) (thickness: 60 nm)·
Second hole transport layer 8: Molybdenum oxide (thickness: 5 nm)
Second electrode 6: An indium-tin composite oxide layer (thickness: 100 nm)

### <Production of Solar Cell>

### Example 1

First, a glass substrate having a thickness of 0.7 mm was prepared.

An indium-tin composite oxide layer having a thickness of 100 nm was formed on the substrate by sputtering. A first electrode was formed in this manner.

Next, an aqueous SnO₂ nanoparticle dispersion (manufactured by Alfa Aesar) was applied to the first electrode by spin coating, baked at 220° C. for 30 minutes, and then subjected to UV ozone treatment to form a tin oxide layer having a thickness of 30 nm. An electron transport layer was formed in this manner.

Next, a raw material solution containing a photoelectric conversion material was applied by spin coating to form a photoelectric conversion layer including a perovskite compound. The raw material solution contained 1.19 mol/L lead (II) iodide (manufactured by Tokyo Chemical Industry Co., Ltd.), 0.06 mol/L lead (II) bromide (manufactured by Tokyo Chemical Industry Co., Ltd.), 0.95 mol/L formamidinium iodide (manufactured by GreatCell Solar Limited), 0.14 mol/L methylammonium iodide (manufactured by GreatCell Solar Limited), 0.06 mol/L methylammonium bromide (manufactured by GreatCell Solar Limited), 0.08 mol/L caesium iodide (manufactured by Iwatani Corporation), and 0.04 mol/L rubidium iodide (manufactured by Iwatani Corporation). The solvent of this solution was a mixture of dimethyl sulfoxide (manufactured by Acros) and N,N-dimethylformamide (manufactured by Acros). A mixing ratio (DMSO:DMF) between dimethyl sulfoxide (DMSO) and N,N-dimethylformamide (DMF) in this raw material solution was 1:4 on a volume basis. The raw material solution was dropped on a surface of the electron transport layer, and then rotation at 2500 rpm was performed. Toluene was dropped 50 seconds after the start of the rotation to form a perovskite intermediate film. This was followed by heating on a hot plate at 170° C. for 10 minutes to form a perovskite film from the intermediate film, and thus a photoelectric conversion layer having a thickness of approximately 400 nm was obtained.

Next, a composition of Example for producing a hole transport body was applied to the photoelectric conversion layer by spin coating to form a hole transport layer. The solvent of the composition for producing a hole transport body was a solution mixture of, on a volume basis, 98% mesitylene (manufactured by KANTO CHEMICAL CO., INC.) and 1% tert-butylpyridine. The composition for producing a hole transport body included 10 g/L PTAA as an organic semiconductor and lithium bis(trifluoromethanesulfonyl)imide as a dopant in an amount of 40 mol % per amount of substance with respect to the mass of the repeating unit of the PTAA. As the composition for producing a hole transport body, three different compositions having different concentrations of 1-methoxyhexane-1-propoxyhexane (SA-9, manufactured by Merck KGaA) serving as a nonionic surfactant were prepared. Specifically, compositions including 0.2 g/L, 0.4 g/L, and 0.8 g/L 1-methoxyhexane-1-propoxyhexane were prepared. Table 1 also shows the proportions (mass %) of the nonionic surfactant in the compositions for producing a hole transport body. Each of the prepared compositions was used to form a hole transport layer after filtered through a 0.2 μm PTFE filter. The solution was applied to the photoelectric conversion layer. Rotation at 1000 rpm was performed for 3 seconds and then stopped. The solvent was vaporized on a hot plate at 60° C., and this was followed by drying on a hot plate at 80° C. for 10 minutes to give a hole transport layer having a thickness of 60 nm.

Subsequently, a molybdenum oxide film was deposited to a thickness of 5 nm on the hole transport layer by vacuum deposition to form a second hole transport layer.

Next, an indium-tin composite oxide layer having a thickness of 100 nm was formed by sputtering. A second electrode was formed in this manner.

Solar cells of Example 1 were obtained in this manner.

### Example 2

The nonionic surfactant included in compositions for producing a hole transport body was changed from 1-methoxyhexane-1-propoxyhexane to glycerol monolaurate (manufactured by Merck KGaA). Two compositions having glycerol monolaurate (manufactured by Merck KGaA) concentrations of 0.2 g/L and 0.4 g/L were prepared as the compositions for producing a hole transport body. Table 1 also shows the proportions (mass %) of the nonionic surfactant in the compositions for producing a hole transport body. Except for these, the compositions for producing a hole transport body were produced in the same manner as in Example 1, and solar cells were produced in the same manner as in Example 1.

### Example 3

The nonionic surfactant included in compositions for producing a hole transport body was changed from 1-methoxyhexane-1-propoxyhexane to sorbitan monolaurate (manufactured by Merck KGaA). Two compositions having sorbitan monolaurate (manufactured by Merck KGaA) concentrations of 0.2 g/L and 0.4 g/L were prepared as the compositions for producing a hole transport body. Table 1 also shows the proportions (mass %) of the nonionic surfactant in the compositions for producing a hole transport body. Except for these, the compositions for producing a hole transport body were produced in the same manner as in Example 1, and solar cells were produced in the same manner as in Example 1.

### Example 4

The nonionic surfactant included in compositions for producing a hole transport body was changed from 1-methoxyhexane-1-propoxyhexane to polyoxyethylene sorbitan monolaurate (Tween 20, manufactured by Merck KGaA). Three compositions having polyoxyethylene sorbitan monolaurate (Tween 20, manufactured by Merck KGaA) concentrations of 0.2 g/L, 0.4 g/L, and 0.8 g/L were prepared as the compositions for producing a hole transport body. Table 1 also shows the proportions (mass %) of the nonionic surfactant in the compositions for producing a hole transport body. Except for these, the compositions for producing a hole transport body were produced in the same manner as in Example 1, and solar cells were produced in the same manner as in Example 1.

### Example 5

The nonionic surfactant included in compositions for producing a hole transport body was changed from 1-methoxyhexane-1-propoxyhexane to polyoxyethylene sorbitan monooleate (Tween 80, manufactured by Merck KGaA). Two compositions having polyoxyethylene sorbitan monooleate (Tween 80, manufactured by Merck KGaA) concentrations of 0.2 g/L and 0.4 g/L were prepared as the compositions for producing a hole transport body. Table 1 also shows the proportions (mass %) of the nonionic surfactant in the compositions for producing a hole transport body. Except for these, the compositions for producing a hole transport body were produced in the same manner as in Example 1, and solar cells were produced in the same manner as in Example 1.

### Example 6

The nonionic surfactant included in compositions for producing a hole transport body was changed from 1-methoxyhexane-1-propoxyhexane to an ethylene oxide-propylene oxide copolymer (PEO5-PPO68-PEO5, Pluronic L121, manufactured by Merck KGaA). Two compositions having ethylene oxide-propylene oxide copolymer (PEO5-PPO68-PEO5, Pluronic L121, manufactured by Merck KGaA) concentrations of 0.4 g/L and 0.8 g/L were prepared as the compositions for producing a hole transport body. Table 1 also shows the proportions (mass %) of the nonionic surfactant in the compositions for producing a hole transport body. Except for these, the compositions for producing a hole transport body were produced in the same manner as in Example 1, and solar cells were produced in the same manner as in Example 1.

### Example 7

The nonionic surfactant included in a composition for producing a hole transport body was changed from 1-methoxyhexane-1-propoxyhexane to n-octyl-α-D-glucopyranoside (α-APG8, manufactured by Merck KGaA). A composition having an n-octyl-α-D-glucopyranoside (α-APG8, manufactured by Merck KGaA) concentration of 0.8 g/L was prepared as the composition for producing a hole transport body. Table 1 also shows the proportion (mass %) of the nonionic surfactant in the composition for producing a hole transport body. Except for these, the composition for producing a hole transport body was produced in the same manner as in Example 1, and a solar cell was produced in the same manner as in Example 1.

### Example 8

The nonionic surfactant included in compositions for producing a hole transport body was changed from 1-methoxyhexane-1-propoxyhexane to polyoxyethylene sorbitan monolaurate (Tween 20, manufactured by Merck KGaA). Three compositions having polyoxyethylene sorbitan monolaurate (Tween 20, manufactured by Merck KGaA) concentrations of 0.05 g/L, 0.1 g/L, and 0.2 g/L were prepared as the compositions for producing a hole transport body. Table 2 also shows the proportions (mass %) of the nonionic surfactant in the compositions for producing a hole transport body. Except for these, the compositions for producing a hole transport body were produced in the same manner as in Example 1. Solar cells were produced in the same manner as in Example 1, except that the compositions for producing a hole transport body were changed, the material of the second electrode was changed from indium-tin composite oxide to gold (Au), the second hole transport layer formed of molybdenum oxide was not formed, and surface treatment was performed by applying an isopropyl alcohol solution in which 1 g/L butylammonium bromide was dissolved by spin coating at 4000 rpm after the photoelectric conversion layer was formed.

### Example 9

The nonionic surfactant included in compositions for producing a hole transport body was changed from 1-methoxyhexane-1-propoxyhexane to polyoxyethylene sorbitan monooleate (Tween 80, manufactured by Merck KGaA). Four compositions having polyoxyethylene sorbitan monooleate (Tween 80, manufactured by Merck KGaA) concentrations of 0.05 g/L, 0.1 g/L, 0.2 g/L, and 0.4 g/L were prepared as the compositions for producing a hole transport body. Table 2 also shows the proportions (mass %) of the nonionic surfactant in the compositions for producing a hole transport body. Except for these, the compositions for producing a hole transport body were produced in the same manner as in Example 1. Solar cells were produced in the same manner as in Example 1, except that the compositions for producing a hole transport body were changed, the material of the second electrode was changed from indium-tin composite oxide to gold (Au), the second hole transport layer formed of molybdenum oxide was not formed, and surface treatment was performed by applying an isopropyl alcohol solution in which 1 g/L butylammonium bromide was dissolved by spin coating at 4000 rpm after the photoelectric conversion layer was formed.

### Comparative Example 1

The surfactant included in compositions for producing a hole transport body was changed from 1-methoxyhexane-1-propoxyhexane to n-hexadecyl β-D-maltoside (manufactured by Merck KGaA) being a nonionic surfactant and having a critical micelle concentration smaller than 0.001 g/L. Three compositions having n-hexadecyl β-D-maltoside (manufactured by Merck KGaA) concentrations of 0.4 g/L, 0.8 g/L, and 1.6 g/L were prepared as the compositions for producing a hole transport body. Table 1 also shows the proportions (mass %) of the nonionic surfactant in the compositions for producing a hole transport body. Except for these, the compositions for producing a hole transport body were produced in the same manner as in Example 1, and solar cells were produced in the same manner as in Example 1.

### Comparative Example 2

The surfactant included in compositions for producing a hole transport body was changed from 1-methoxyhexane-1-propoxyhexane to dodecyltrimethylammonium bromide (manufactured by Merck KGaA) being a cationic surfactant. Three compositions having dodecyltrimethylammonium bromide (manufactured by Merck KGaA) concentrations of 0.4 g/L, 0.8 g/L, and 1.6 g/L were prepared as the compositions for producing a hole transport body. Table 1 also shows the proportions (mass %) of the nonionic surfactant in the compositions for producing a hole transport body. Except for these, the compositions for producing a hole transport body were produced in the same manner as in Example 1, and solar cells were produced in the same manner as in Example 1.

### Comparative Example 3

1-Methoxyhexane-1-propoxyhexane was not added to the composition for producing a hole transport body. That is, a composition of Comparative Example 3 for producing a hole transport body was surfactant-free. Except for this, the composition for producing a hole transport body was produced in the same manner as in Example 1, and a solar cell was produced in the same manner as in Example 1.

### Comparative Example 4

Polyoxyethylene sorbitan monolaurate (Tween 20, manufactured by Merck KGaA) was not added to the composition for producing a hole transport body. That is, a composition of Comparative Example 4 for producing a hole transport body was surfactant-free. Except for this, the composition for producing a hole transport body was produced in the same manner as in Example 8, and a solar cell was produced in the same manner as in Example 8.

### Comparative Example 5

The surfactant included in a composition for producing a hole transport body was changed from 1-methoxyhexane-1-propoxyhexane to dodecyl sodium sulfate (manufactured by Merck KGaA) being an anionic surfactant. A composition having a dodecyl sodium sulfate (manufactured by Merck KGaA) concentration of 0.8 mg/L was prepared as the composition for producing a hole transport body. However, the dodecyl sodium sulfate did not dissolve in the raw material solution. Therefore, in Comparative Example 5, a hole transport body was unable to be produced, and no solar cell was produced, either. Note that the dodecyl sodium sulfate has a critical micelle concentration of 2.384 g/L.

### Comparative Example 6

The surfactant included in a composition for producing a hole transport body was changed from 1-methoxyhexane-1-propoxyhexane to N-dodecyl-N,N-dimethyl-3-ammonio-1-propanesulfonic acid being a zwitterionic surfactant. A composition having an N-dodecyl-N,N-dimethyl-3-ammonio-1-propanesulfonic acid concentration of 0.8 mg/L was prepared as the composition for producing a hole transport body. However, the N-dodecyl-N, N-dimethyl-3-ammonio-1-propanesulfonic acid did not dissolve in the raw material solution. Therefore, in Comparative Example 6, a hole transport body was unable to be produced, and no solar cell was produced, either. Note that N-dodecyl-N, N-dimethyl-3-ammonio-1-propanesulfonic acid has a critical micelle concentration of 1.107 g/L.

### Comparative Example 7

The surfactant included in a composition for producing a hole transport body was changed from 1-methoxyhexane-1-propoxyhexane to an ethylene oxide-propylene oxide copolymer (PEO95-PPO62-PEO95, Pluronic L127, manufactured by Merck KGaA) being a nonionic surfactant. A composition having an ethylene oxide-propylene oxide copolymer (PEO95-PPO62-PEO95, Pluronic L127, manufactured by Merck KGaA) concentration of 0.8 mg/L was prepared as the composition for producing a hole transport body. However, this composition was liquid-repellent, and thus a hole transport body was unable to be produced. Therefore, in Comparative Example 7, no solar cell was produced, either. Note that the ethylene oxide-propylene oxide copolymer (PEO95-PPO62-PEO95, Pluronic L127, manufactured by Merck KGaA) has a critical micelle concentration of 50.000 g/L.

### Comparative Example 8

The surfactant included in a composition for producing a hole transport body was changed from 1-methoxyhexane-1-propoxyhexane to polyoxyethylene octylphenyl ether being a nonionic surfactant. A composition having a polyoxyethylene octylphenyl ether concentration of 0.8 mg/L was prepared as the composition for producing a hole transport body. However, the polyoxyethylene octylphenyl ether did not dissolve in the raw material solution. Therefore, in Comparative Example 8, a hole transport body was unable to be produced, and no solar cell was produced, either. Note that the polyoxyethylene octylphenyl ether has a critical micelle concentration of 0.150 g/L.

### Comparative Example 9

The surfactant included in a composition for producing a hole transport body was changed from 1-methoxyhexane-1-propoxyhexane to polyoxyethylene lauryl ether being a nonionic surfactant. A composition having a polyoxyethylene lauryl ether concentration of 0.8 mg/L was prepared as the composition for producing a hole transport body. However, the polyoxyethylene lauryl ether did not dissolve in the raw material solution. Therefore, in Comparative Example 9, a hole transport body was unable to be produced, and no solar cell was produced, either. Note that the polyoxyethylene lauryl ether has a critical micelle concentration of 0.123 g/L.

### <Measurement of Critical Micelle Concentration of Surfactant>

The critical micelle concentrations of the surfactants used in Examples and Comparative Examples were measured by the following method. A solution in which each surfactant was dissolved in pure water was prepared, and the concentration dependence of a surface tension was determined using this solution by the Wilhelmy plate method. The surfactant concentration at which the surface tension became constant was employed as the critical micelle concentration. Table 1 shows the results. In Table 1, the critical micelle concentration is denoted as “CMC”.

<Measurement of Contact Angle of Composition for Producing Hole Transport Body>

A glass substrate was subjected to UV ozone treatment, a drop of each composition was put on a surface of the glass substrate with a micropipette, and the drop was observed and recorded with a CCD camera to measure the contact angle. FAMAS (manufactured by Kyowa Interface Science Co., Ltd.) was used for the contact angle measurement. Table 1 shows the results. In Table 1, the contact angle is denoted as “CA”.

### <Evaluation of Solar Cell>

Current-voltage characteristics of the solar cells of Examples 1 to 9 and Comparative Examples 1 to 4 were measured in an inert atmosphere.

An electrochemical analyzer (ALS440B manufactured by BAS Inc.) and a xenon light source (BPS X300BA manufactured by Bunkoukeiki Co., Ltd.) were used for the measurement of the current-voltage characteristics of the solar cell. Before the measurement, the light intensity was calibrated so as to be 1 Sun (100 mW/cm²) using a silicon photodiode. A voltage scan rate was 100 mV/s. Before starting the measurement, each solar cell was irradiated with indoor light for about one hour to stabilize the state. Each solar cell was masked with a black mask having a 0.1 cm² opening portion so as to fix the effective area and reduce influence of scattering light. The masked solar cell was irradiated with light from the mask (substrate) side. By this method, the current-voltage characteristics of the solar cells of Examples and Comparative Examples were measured, and the power conversion efficiencies (PCE) thereof was determined.

The current-voltage characteristics of the solar cells of Examples 1 to 7 and Comparative Examples 1 to 3 were measured for the solar cells in an initial state, after a light resistance test, and after a light resistance and thermal resistance test. “Initial” indicates the solar cells were measured immediately after produced. “After the light resistance test” indicates the solar cells were measured after irradiated at 1 Sun for 135 hours at a substrate surface temperature of 50° C. “After the light resistance and thermal resistance test” indicates that the solar cells were measured after irradiated at 1 Sun for 135 hours at a substrate surface temperature of 50° C., heated in a dark place at 85° C. for 66 hours, and then irradiated at 1 Sun for 23 hours. The current-voltage characteristics of the solar cells of Example 8, Example 9, and Comparative Example 4 were measured only for the solar cells in the initial state.

Tables 1 and 2 show the results for measuring the power conversion efficiencies (PCE) of the solar cells of Examples and Comparative Examples. Tables 1 and 2 also show the open-circuit voltages (V_{oc}), the short-circuit current densities (J_{SC}), and the fill factors (FF).

TABLE 1

| | | CMC | CA | Concentration | Concentration |
|---|---|---|---|---|---|
| | Surfactant | (g/L) | (°) | (g/L) | (mass %) |
| Ex. 1 | 1-Methoxyhexane- | 0.019 | 11.2 | 0.8 | 0.09 |
| | 1-propoxyhexane | | 8.1 | 0.4 | 0.045 |
| | | | 15.9 | 0.2 | 0.022 |
| Ex. 2 | Glycerol monolaurate | 0.011 | 17.6 | 0.4 | 0.045 |
| | | | 21.1 | 0.2 | 0.022 |
| Ex. 3 | Sorbitan monolaurate | 0.014 | 12.7 | 0.4 | 0.045 |
| | | | 14.8 | 0.2 | 0.022 |
| Ex. 4 | Polyoxyethylene sorbitan | 0.080 | 4.6 | 0.8 | 0.09 |
| | monolaurate | | 7.8 | 0.4 | 0.045 |
| | (Tween 20) | | 14.7 | 0.2 | 0.022 |
| Ex. 5 | Polyoxyethylene sorbitan | 0.016 | 12.1 | 0.4 | 0.045 |
| | monooleate | | | | |
| | (Tween 80) | | 14.8 | 0.2 | 0.022 |
| Ex. 6 | Ethylene oxide- | 0.004 | 29.4 | 0.8 | 0.09 |
| | propylene oxide copolymer | | | | |
| | (Pluronic L121) | | 29.5 | 0.4 | 0.045 |
| Ex. 7 | n-Octyl-α-D- | 0.003 | 28.9 | 0.8 | 0.09 |
| | glucopyranoside | | | | |
| Comp. | n-Hexadecyl β-D-maltoside | 0.0003 | 14.4 | 1.6 | 0.18 |
| Ex. 1 | | | 17.2 | 0.8 | 0.09 |
| | | | 16.7 | 0.4 | 0.045 |
| Comp. | Dodecyltrimethylammonium | 4.317 | 18.5 | 1.6 | 0.18 |
| Ex. 2 | bromide | | 16.3 | 0.8 | 0.09 |
| | | | 20.8 | 0.4 | 0.045 |
| Comp. | Not added | — | 30.8 | 0 | 0 |
| Ex. 3 | | | | | |

| | | | | | | | | | | Light resistance 135 h | | | |
|---|---|---|---|---|---|---|---|---|---|---|---|---|---|
| | | | | | | | | | | → Heat resistance 66 h | | | |
| | | Initial | | | | Light resistance 135 h | | | | → Light resistance 23 h | | | |
| | | Voc | Jsc | FF | PCE | Voc | Jsc | FF | PCE | Voc | Jsc | FF | PCE |
| | Surfactant | (V) | (mA/cm²) | (%) | (%) | (V) | (mA/cm²) | (%) | (%) | (V) | (mA/cm²) | (%) | (%) |
| Ex. 1 | 1-Methoxyhexane- | 1.06 | 21.4 | 0.66 | 14.9 | 1.05 | 20.9 | 0.66 | 14.4 | 1.00 | 20.0 | 0.55 | 11.0 |
| | 1-propoxyhexane | 1.03 | 21.3 | 0.73 | 16.1 | 1.03 | 20.7 | 0.63 | 13.5 | 1.00 | 20.3 | 0.56 | 11.4 |
| | | 1.02 | 21.2 | 0.68 | 14.9 | 1.03 | 20.7 | 0.62 | 13.4 | 1.00 | 20.7 | 0.58 | 11.9 |
| Ex. 2 | Glycerol | 1.02 | 21.2 | 0.71 | 15.4 | 1.02 | 20.4 | 0.61 | 12.6 | 0.99 | 19.9 | 0.59 | 11.6 |
| | monolaurate | 1.00 | 21.4 | 0.74 | 16.0 | 1.02 | 20.8 | 0.65 | 13.8 | 0.99 | 21.0 | 0.59 | 12.3 |
| Ex. 3 | Sorbitan | 1.03 | 21.2 | 0.71 | 15.5 | 1.02 | 20.2 | 0.59 | 12.2 | 1.00 | 19.4 | 0.56 | 10.9 |
| | monolaurate | 1.01 | 21.3 | 0.72 | 15.4 | 1.02 | 20.3 | 0.59 | 12.4 | 1.00 | 19.7 | 0.57 | 11.3 |
| Ex. 4 | Polyoxyethylene | 1.07 | 21.1 | 0.66 | 15.0 | 1.05 | 20.1 | 0.61 | 12.9 | 1.00 | 18.8 | 0.54 | 10.1 |
| | sorbitan | | | | | | | | | | | | |
| | monolaurate | 1.08 | 21.4 | 0.70 | 16.3 | 1.05 | 20.7 | 0.63 | 13.6 | 0.99 | 19.3 | 0.55 | 10.5 |
| | (Tween 20) | 1.07 | 21.2 | 0.68 | 15.4 | 1.04 | 20.5 | 0.61 | 13.0 | 0.99 | 19.4 | 0.55 | 10.8 |
| Ex. 5 | Polyoxyethylene | 1.08 | 21.3 | 0.69 | 16.1 | 1.05 | 20.4 | 0.62 | 13.3 | 1.00 | 20.0 | 0.57 | 11.5 |
| | sorbitan | | | | | | | | | | | | |
| | monooleate | 1.09 | 21.2 | 0.72 | 16.7 | 1.05 | 20.4 | 0.61 | 13.1 | 1.00 | 19.8 | 0.58 | 11.6 |
| | (Tween 80) | | | | | | | | | | | | |
| Ex. 6 | Ethylene oxide- | 1.05 | 21.1 | 0.68 | 15.1 | 1.03 | 20.6 | 0.63 | 13.4 | 0.99 | 21.0 | 0.59 | 12.3 |
| | propylene oxide | | | | | | | | | | | | |
| | copolymer | 1.04 | 21.3 | 0.73 | 16.1 | 1.04 | 20.8 | 0.63 | 13.6 | 0.99 | 21.1 | 0.60 | 12.6 |
| | (Pluronic L121) | | | | | | | | | | | | |
| Ex. 7 | n-Octyl-α-D- | 1.06 | 21.2 | 0.72 | 16.1 | 1.05 | 20.8 | 0.66 | 14.3 | 1.02 | 20.7 | 0.64 | 13.6 |
| | glucopyranoside | | | | | | | | | | | | |
| Comp. | n-Hexadecyl β-D- | 1.01 | 18.5 | 0.48 | 9.0 | 0.55 | 4.9 | 0.24 | 0.6 | 0.56 | 4.1 | 0.25 | 0.5 |
| Ex. 1 | maltoside | 1.01 | 19.1 | 0.50 | 9.6 | 0.61 | 10.3 | 0.25 | 1.6 | 0.67 | 7.4 | 0.24 | 1.2 |
| | | 1.02 | 20.0 | 0.57 | 11.7 | 0.75 | 14.1 | 0.31 | 3.3 | 0.77 | 10.0 | 0.28 | 2.2 |
| Comp. | Dodecyltrimethyl- | 1.03 | 14.8 | 0.35 | 5.3 | 0.72 | 2.1 | 0.28 | 0.4 | 0.92 | 2.4 | 0.29 | 0.6 |
| Ex. 2 | ammonium | 0.95 | 19.1 | 0.53 | 9.5 | 0.51 | 16.1 | 0.37 | 3.0 | 0.80 | 12.1 | 0.30 | 2.9 |
| | bromide | 0.98 | 19.6 | 0.58 | 11.2 | 0.66 | 15.3 | 0.36 | 3.8 | 0.84 | 11.1 | 0.32 | 3.2 |
| Comp. | Not added | 0.99 | 21.4 | 0.74 | 15.7 | 1.00 | 20.5 | 0.57 | 11.6 | 0.97 | 19.7 | 0.49 | 9.6 |
| Ex. 3 | | | | | | | | | | | | | |

TABLE 2

| | | Concentration | Concentration | Voc | Jsc | FF | PCE |
|---|---|---|---|---|---|---|---|
| | Surfactant | (g/L) | (mass %) | (V) | (mA/cm²) | (%) | (%) |
| Example 8 | Polyoxyethylene | 0.2 | 0.022 | 1.10 | 21.8 | 0.68 | 16.3 |
| | sorbitan monolaurate | 0.1 | 0.011 | 1.08 | 22.1 | 0.72 | 17.3 |
| | (Tween 20) | 0.05 | 0.0056 | 1.07 | 22.1 | 0.73 | 17.2 |
| Example 9 | Polyoxyethylene | 0.4 | 0.045 | 1.17 | 21.1 | 0.60 | 14.7 |
| | sorbitan monooleate | 0.2 | 0.022 | 1.15 | 21.3 | 0.67 | 16.5 |
| | (Tween 80) | 0.1 | 0.011 | 1.13 | 21.4 | 0.67 | 16.3 |
| | | 0.05 | 0.0056 | 1.11 | 21.5 | 0.66 | 16.1 |
| Comparative | Not added | 0 | 0 | 0.98 | 19.2 | 0.66 | 12.5 |
| Example 4 | | | | | | | |

### <Comparison of Power Conversion Efficiencies>

The nonionic surfactant having a critical micelle concentration of 0.001 g/L or more and 0.080 g/L or less was added to the hole transport layer of each of the solar cells of Examples 1 to 7. For the light resistance and the thermal resistance of the solar cells of Examples 1 to 7, it has been confirmed that when the solar cells were actually used for power generation, the open-circuit voltage (V_{oc}) and the fill factor (FF) were high and consequently the power conversion efficiency (PCE) were high.

On the other hand, in the case where, as in Comparative Example 1, the nonionic surfactant having a critical micelle concentration of less than 0.001 g/L was added to the hole transport layer, all property parameters were low and consequently the power conversion efficiency was low. Additionally, in the case where, as in Comparative Example 2, the cationic surfactant was added, all property parameters and the power conversion efficiency were low, and no improvement in performance was observed. It is inferred that in the case where the surfactant was a cationic surfactant, its action on a dopant molecule was so strong that, although the contact angle was able to be reduced, the doping function was hindered.

According to comparison of the photoelectric conversion efficiencies of the solar cells of Example 8, Example 9, and Comparative Example 4 having the same configuration except for the hole transport layer, the solar cells of Examples 8 and 9 each including the hole transport layer including the nonionic surfactant having a critical micelle concentration of 0.001 g/L or more and 0.080 g/L or less have higher conversion efficiencies than that of the solar cell of Comparative Example 4 including the hole transport layer free of a nonionic surfactant.

### <Effect of Surfactant>

Examples and Comparative Examples described above have revealed that there is an appropriate critical micelle concentration range for the nonionic surfactants. A nonionic surfactant having too high a critical micelle concentration is so hydrophilic that the nonionic surfactant does not dissolve in the solvent (in this case, a non-polar solvent) of the composition for a hole transport layer. On the other hand, a nonionic surfactant having too low a critical micelle concentration is so lipophilic that the nonionic surfactant dissolves well but the power conversion efficiency is low. This indicate that nonionic surfactants rather prevent dispersion of polar molecules being a doping material and formation of a uniform hole transport layer.

### INDUSTRIAL APPLICABILITY

The present disclosure can improve the power conversion efficiency of a photoelectric conversion element using a hole transport body including a particular nonionic surfactant. Therefore, the hole transport body of the present disclosure can be included in a photoelectric conversion element, such as a solar cell.

What is claimed is:

1. A hole transport body comprising:
an organic semiconductor; and
a nonionic surfactant having a critical micelle concentration of 0.001 g/L or more and 0.080 g/L or less in pure water.

2. The hole transport body according to claim 1, further comprising a dopant.

3. The hole transport body according to claim 1, wherein the nonionic surfactant includes an alkyl hexyl ether in which the number of carbon atoms in an alkyl group is 1 or more and 5 or less.

4. The hole transport body according to claim 3, wherein the alkyl hexyl ether includes at least one selected from the group consisting of methyl hexyl ether, ethyl hexyl ether, normal propyl hexyl ether, normal butyl hexyl ether, and normal pentyl hexyl ether.

5. The hole transport body according to claim 1, wherein the nonionic surfactant includes an ester compound obtained by a condensation reaction between a sugar alcohol or an intramolecular dehydration condensation product of a sugar alcohol and a fatty acid.

6. The hole transport body according to claim 5, wherein the ester compound includes a fatty acid ester in which the number of carbon atoms in an alkyl group is 12 or more and 15 or less.

7. The hole transport body according to claim 5, wherein the ester compound includes a glycerin fatty acid ester.

8. The hole transport body according to claim 5, wherein the ester compound includes a sorbitan fatty acid ester.

9. The hole transport body according to claim 5, wherein the ester compound includes glycerin monolaurate.

10. The hole transport body according to claim 5, wherein the ester compound includes a fatty acid ester of an intramolecular dehydration condensation product of a sugar alcohol, the intramolecular dehydration condensation being modified with polyethylene glycol.

11. The hole transport body according to claim 10, wherein the polyethylene glycol includes 1 or more and 22 or less ethylene glycol units as constituent monomer units.

12. The hole transport body according to claim 10, wherein the fatty acid ester of the intramolecular dehydration condensation product of the sugar alcohol includes a monolaurate.

13. The hole transport body according to claim 10, wherein the fatty acid ester of the intramolecular dehydration condensation product of the sugar alcohol includes a monooleate.

14. The hole transport body according to claim 1, wherein the nonionic surfactant includes a copolymer of polyethylene glycol and polypropylene glycol.

15. The hole transport body according to claim 14, wherein the copolymer includes 6 or more and 53 or less ethylene glycol units and 42 or more and 69 or less propylene glycol units as constituent monomer units.

16. The hole transport body according to claim 1, wherein the nonionic surfactant includes a glucoside derivative.

17. The hole transport body according to claim 16, wherein the glucoside derivative is an alkyl glucoside derivative.

18. The hole transport body according to claim 17, wherein the alkyl glucoside derivative is n-octyl-α-D-glucopyranoside.

19. The hole transport body according to claim 1, wherein the organic semiconductor includes at least one selected from the group consisting of 2,2′,7,7′-tetrakis[N,N-di-P-methoxyphenylamino]-9,9′-spirobifluorene, poly[bis(4-phenyl)(2,4,6-triphenylmethyl)amine], poly(3-hexylthiophene-2,5-diyl), poly(3,4-ethylenedioxythiophene), copper phthalocyanine, a derivative of 2,2′,7,7′-tetrakis[N,N-di-P-methoxyphenylamino]-9,9′-spirobifluorene, a derivative of poly[bis(4-phenyl)(2,4,6-triphenylmethyl)amine], a derivative of poly(3-hexylthiophene-2,5-diyl), a derivative of poly(3,4-ethylenedioxythiophene), and a derivative of copper phthalocyanine.

20. The hole transport body according to claim 2, wherein the dopant includes at least one selected from the group consisting of lithium hexafluorophosphate, lithium borofluoride, lithium perchlorate, lithium bis(pentafluoroethanesulfonyl)imide, bis(trifluoromethanesulfonyl)amine, lithium bis(trifluoromethanesulfonyl)imide, zinc bis(trifluoromethanesulfonyl)imide, tris[2-(1H-pyrazole-1-yl)-4-tert-butylpyridine]cobalt, 4-isopropyl-4-methyl diphenyl iodonium tetrakis(pentafluorophenyl)borate, tris(pentafluorophenyl)borane, 2,3,5,6-tetrafluoro-7,7,8,8-tetracyano-quinodimethane, and 1,2,3,4,8,9,10,11,15,16,17,18,22,23,24,25-hexadecafluoro-29H,31H-phthalocyanine.

21. The hole transport body according to claim 1, wherein a proportion of the nonionic surfactant is 0.5 mass % or more and 36 mass % or less.

22. A hole transport body comprising:
an organic semiconductor; and
a nonionic surfactant, wherein
the nonionic surfactant includes an alkyl hexyl ether in which the number of carbon atoms in an alkyl group is 1 or more and 5 or less.

23. The hole transport body according to claim 22, wherein the alkyl hexyl ether includes at least one selected from the group consisting of methyl hexyl ether, ethyl hexyl ether, normal propyl hexyl ether, normal butyl hexyl ether, and normal pentyl hexyl ether.

24. A photoelectric conversion element comprising: a first electrode; a hole transport layer; a photoelectric conversion layer; and a second electrode, wherein
the hole transport layer includes the hole transport body according to claim 1.

25. The photoelectric conversion element according to claim 24, wherein the photoelectric conversion layer includes a perovskite compound.

26. The photoelectric conversion element according to claim 25, wherein
the perovskite compound is composed of a monovalent cation, a divalent cation, and a halogen anion, and
the divalent cation includes at least one selected from the group consisting of a Sn cation, a Ge cation, and a Pb cation.

27. A composition for producing a hole transport body, the composition comprising:
an organic semiconductor;
a nonionic surfactant having a critical micelle concentration of 0.001 g/L or more and 0.080 g/L or less in pure water; and
a solvent.

28. The composition according to claim 27, wherein a proportion of the nonionic surfactant in the composition is more than 0 g/L and 1 g/L or less.

29. The composition according to claim 27, wherein a contact angle of the composition on a surface of glass subjected to UV ozone treatment is 7° or more and 30° or less at 24° C.

30. A composition for producing a hole transport body, the composition comprising:
an organic semiconductor;
a nonionic surfactant; and
a solvent, wherein
the nonionic surfactant includes an alkyl hexyl ether in which the number of carbon atoms in an alkyl group is 1 or more and 5 or less.

31. The composition according to claim 30, wherein the alkyl hexyl ether includes at least one selected from the group consisting of methyl hexyl ether, ethyl hexyl ether, normal propyl hexyl ether, normal butyl hexyl ether, and normal pentyl hexyl ether.
